(19) United States
(12) Patent Application Publication
(10) Pub. No.: US 2006/0094257 A1
(43) Pub. Date: May 4, 2006

(54) Low thermal budget dielectric stack for SONOS nonvolatile memories

(75) Inventors: Alon Hoffman, Haifa (IL); Rachel Edrei, Haifa (IL); Meirav Saraf, Ramat-Gan (IL); Yakov Roizin, Afula (IL); Ruth Shima-Edelstein, Haifa (IL)

Correspondence Address: BEVER HOFFMAN & HARMS, LLP;TRI-VALLEY OFFICE, 1432 CONCANNON BLVD., BLDG. G, LIVERMORE, CA, 94550, US

(73) Assignee: Tower Semiconductor Ltd., Migdal Haemek (IL)

(21) Appl. No.: 11/267,928

(22) Filed: Nov. 3, 2005

Related U.S. Application Data
(60) Provisional application No. 60/625,736, filed on Nov. 4, 2004.

(51) Int. Cl. H01L 21/31; H01L 21/469

(52) U.S. Cl. 438/778

(57) ABSTRACT

A method of forming an oxide-nitride-oxide (ONO) structure for use in a non-volatile memory cell, which includes (1) forming a first oxide layer over a substrate, (2) forming a silicon nitride layer over the first oxide layer, (3) introducing oxygen into a top interface of the silicon nitride layer, and then (4) forming a second oxide layer over the silicon nitride layer.

### RELATED APPLICATION

This application claims priority of U.S. Provisional Patent Application 60/625,736, entitled “Low Thermal Budget Dielectric Stack For SONOS Nonvolatile Memories” filed Nov. 4, 2004.

### FIELD OF THE INVENTION

The present invention relates to silicon-oxide-nitride-oxide-silicon (SONOS) non-volatile memory. More specifically, the present invention relates to forming an oxide-nitride-oxide (ONO) structure with a low thermal budget.

### PRIOR ART

FIG. 1 is a cross sectional view of a conventional nitride read only memory (NROM) non-volatile memory (NVM) cell 100, which implements a SONOS structure. NROM cell 100 includes p-type substrate 101, N+ source/drain (and diffusion bit line) regions 111-112, channel region 113, oxide-nitride-oxide (ONO) structure 120, bit line oxide regions 131-132 and polysilicon control gate (and word line) 140. ONO structure 120 includes lower silicon oxide layer 121, silicon nitride layer 122 and upper silicon oxide layer 123. NROM cell 100 features two-bit per cell storage, with two data bits being stored in two separate charge trapping regions 122L and 122R in nitride layer 122. Thus, data is stored as charges in the ONO structure 120 at the edges of a memory transistor channel 113. NROM cell 100 is described in more detail in U.S. Pat. No. 5,768,192, to Eitan.

Programming NROM cell 100 requires increasing the threshold voltage of the cell. Programming typically involves applying a positive voltage to the gate 140 and a positive voltage to the drain (111 or 112) while the source (112 or 111) is grounded. The channel electrons are accelerated in the lateral field. The electrons eventually achieve sufficient energy to be injected in the vertical field into the silicon nitride layer 122, this being known as hot electron injection. When the drain and the gate voltages are no longer present, the bottom oxide layer 121 and the top oxide layer 123 of the ONO structure 120 prevent electrons from moving to the substrate 101 or the gate 140. An erase operation is performed by injecting holes generated in the drain (111 or 112) into the ONO structure 120 by a band-to-band tunneling mechanism. During the erase operation, a positive voltage is applied to the drain (111 or 112) and a negative (or zero) voltage is applied to the gate 140.

There are special requirements associated with the charge trapping media (e.g., silicon nitride layer 122). For example, the density of the charge traps must be high enough to allow storage of large charges in a small volume. In addition, the activation energy of the traps must be high enough to suppress lateral redistribution of trapped electrons (e.g., during retention bakes).

The above conditions are satisfied in conventional ONO structures where the top oxide layer 123 is fabricated by pyrogenic (mixture of O₂ and H₂ in the presence of a catalizator) silicon nitride oxidation at temperatures in the range of 1000-1050° C. In this case, a silicon oxynitride layer (not shown) is grown at the top of a silicon nitride surface that contains the necessary deep traps with high concentration and activation energy. The following publications provide details of pyrogenic silicon nitride oxidation: Z. A. Weinberg, et al., “Ultrathin oxide-nitride-oxide films”, Appl. Phys. Lett., 57 (12) (17 Sep. 1990) pp. 1248-1250; and V. A. Gritsenko, et al., “Enriching of the Si₃N₄—Thermal Oxide Interface by Excess Silicon in ONO Structure”, Microelectronic Engineering 36 (1997) pp. 123-124.

If the density of the traps is not sufficient, attempts to program the memory cell to a high threshold voltage will be not successful or will result in lateral spread of the locally trapped charge (i.e., all the traps in the nitride above the initial injection point are filled). In this case, it is difficult to erase the memory cell 100 because the holes generated in the drain region do not reach the trapped electrons spread in the direction of the channel 113.

The above-described ONO structure 120, commonly referred to as “high thermal budget” ONO, has been successfully used in NROM memories and guaranteed high retention time and large programming windows. Nevertheless, application of high thermal budget ONO in non-volatile memories is limited. This is because high thermal budget ONO must be fabricated at the very beginning of the process flow, after shallow trench isolation (STI) formation. Otherwise, the memory cell diffusion regions (e.g., source/drain regions 111-112) will spread during the formation of top oxide layer 123, when the temperature exceeds 1000° C. Integration of a high thermal budget ONO structure 120 can also have a negative influence on the STI isolation.

An ONO structure fabricated with a low thermal oxidation budget (as opposed to a furnace thermal oxidation thermal budget), is reported in published U.S. Patent Application 2003-0017670, by Luoh et al., filed Jul. 20, 2001. Luoh et al. teach that an oxynitride layer is formed by an in situ steam generation (ISSG) technique. This low thermal budget oxidation is similar to pyrogenic high temperature oxidation, but is performed in a rapid thermal anneal (RTA) system and thus requires a shorter time to complete. Luoh et al. also describe other techniques of oxynitride deposition, including well-known standard thermal processes of nitride oxidation in O₂, NO and N₂O at high temperatures.

The capability of forming the upper oxide layer of an ONO structure with a low thermal budget would advantageously allow scaling of the total ONO structure thickness. Scalability of the ONO thickness is desirable because a thin ONO structure will typically exhibit pinholes and poor electrical properties in the silicon nitride layer, thereby resulting in low breakdown voltages and current leakage.

It would therefore be desirable to be able to fabricate an ONO structure having the same chemical content as a high thermal budget ONO structure 120, but with a lower thermal budget. Note that the thermal budget of an operation refers to the total amount of thermal energy transferred to the wafer during the operation, and is proportional to temperature and duration of the process.

### SUMMARY

Accordingly, the present invention provides an improved method for fabricating an ONO structure having a low thermal budget. The method of the present invention results in the creation of an ONO stack that exhibits a high density of charge traps, wherein the charge traps exhibit a high activation energy. The method of the present invention requires a much lower thermal budget than a conventional high thermal budget ONO structure (FIG. 1).

The present invention includes method of forming an oxide-nitride-oxide (ONO) structure for use in a non-volatile memory cell, which includes (1) forming a first oxide layer over a substrate, (2) forming a silicon nitride layer over the first oxide layer, (3) introducing oxygen into a top interface of the silicon nitride layer, and then (4) forming a second oxide layer over the silicon nitride layer. In accordance with one embodiment, oxygen ions can be implanted into the top interface of the silicon nitride layer by an oxygen plasma. Introducing oxygen into the silicon nitride layer before forming the upper oxide layer advantageously allows the upper oxide layer to be fabricated using a low thermal budget process, while allowing silicon oxynitride to be formed in portions of the silicon nitride layer. The second oxide layer can be formed, for example, by a low thermal budget high temperature oxide process, or by chemical vapor deposition. The second oxide layer can alternately be formed of a high dielectric constant material, such as aluminum oxide, hafnium oxide or zirconium oxide.

The present invention will be more fully understood in view of the following description and drawings.

### BRIEF DESCRIPTION OF THE DRAWINGS

FIG. 1 is a cross sectional view of a conventional NROM cell.

FIGS. 2A-2D are cross sectional views of an ONO structure during various stages of fabrication, in accordance with one embodiment of the present invention.

FIGS. 3, 4 and 5 are graphs illustrating the concentration percentage of silicon, oxygen and nitrogen in silicon nitride layers exposed to oxygen plasma for 30, 60 and 120 seconds, respectively, in accordance with the present invention.

FIG. 6 is a graph illustrating the concentration percentage of silicon, oxygen and nitrogen measured in silicon nitride layers of conventional high thermal budget ONO structures.

FIG. 7 is a graph comparing the threshold voltage loss associated with three groups of NROM cells, including conventional NROM cells, NROM cells fabricated in accordance with the present invention, and NROM cells fabricated without exposing the associated silicon nitride layer to oxygen.

### DETAILED DESCRIPTION

An improved method for forming an ONO structure for a SONOS non-volatile memory device is provided. The method includes forming a bottom oxide layer over a substrate, and then forming a silicon nitride layer over the bottom oxide layer. The top surface of the silicon nitride layer is then processed in oxygen, such that a silicon oxynitride media with deep traps is subsequently created for charge storage. The oxygen processing may include, for example, bombarding the top surface of the silicon nitride layer with oxygen ions from an oxygen plasma. After the top surface of the silicon nitride layer has been processed in oxygen, a top oxide layer is formed over the silicon nitride layer. The oxygen processing of the silicon nitride layer allows oxide incorporation into the top surface of the silicon nitride layer at a low temperature, and creates suitable traps for two-bit per cell operation of SONOS devices. As a result, the ONO structure of the present invention requires a significantly smaller thermal budget than a conventional high thermal budget ONO structure.

The present invention seeks to provide an improved ONO structure for embedded nonvolatile memory devices with oxide-nitride-oxide layers, such as, but not limited to, embedded NROM devices. Although the invention is not limited to embedded NROM devices, for the sake of simplicity, the advantages of the invention are described below with reference to embedded NROM devices.

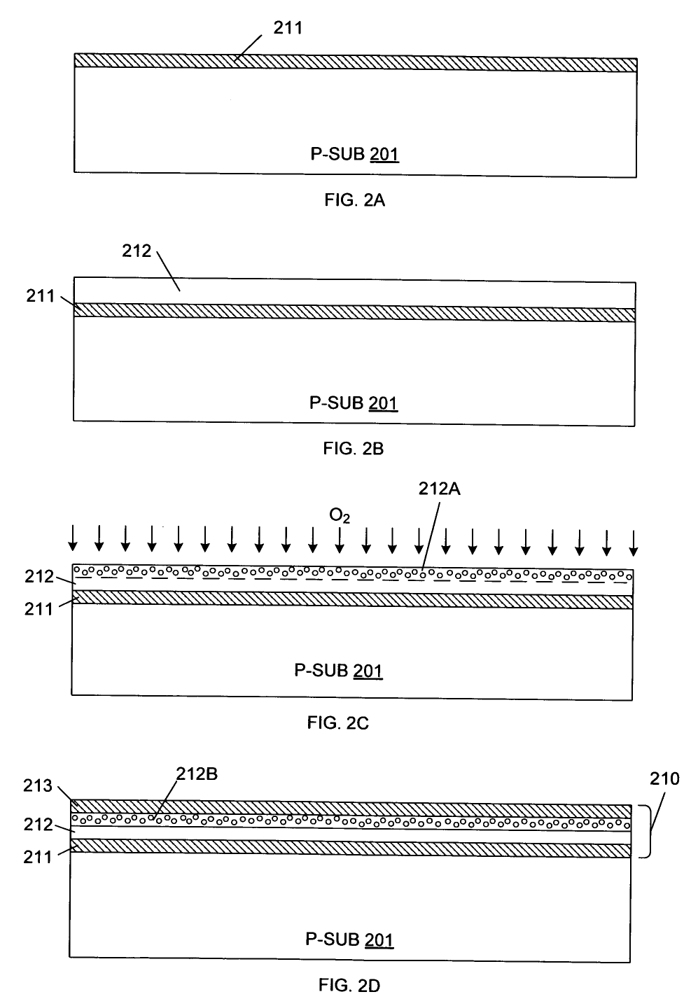

FIGS. 2A-2D are cross sectional views of an ONO structure 210 of the present invention during various process steps. As illustrated in FIG. 2A, a bottom oxide layer 211 is formed over an upper surface of a semiconductor substrate 201. In the described embodiment, substrate 201 is p-type monocrystalline silicon. The bottom oxide layer 211 can be fabricated using the same growth conditions used in a conventional ONO structure. For example, bottom oxide layer 211 can be silicon oxide formed by dry thermal oxidation of the underlying silicon substrate 201. Bottom oxide layer 211 can be formed in other manners in other embodiments. The thickness of bottom oxide layer 211 is selected to prevent (or minimize) the leakage of charge between the subsequently formed silicon nitride layer 212 and substrate 201. In a particular embodiment, the thickness of bottom oxide layer 211 is about 70 Angstroms.

As illustrated in FIG. 2B, silicon nitride layer 212 is subsequently formed over bottom oxide layer 211. Silicon nitride layer 212 can be fabricated using the same growth conditions used in a conventional ONO structure. For example, silicon nitride layer 212 can be formed by chemical vapor deposition (CVD) of silicon nitride from diclorosilane/ammonia mixture (1:10) at 680° C., with a deposited silicon nitride thickness of about 116 Angstroms. Other conventional methods of forming a silicon nitride layer can be used in other embodiments. Moreover, silicon nitride layer 212 can have other thicknesses in other embodiments.

As illustrated in FIG. 2C, the upper surface of silicon nitride layer 212 is bombarded with high doses of low-energy oxygen ions, which are implanted into an upper region 212A of silicon nitride layer 212. The amount of oxygen incorporated into the silicon nitride layer 212 is selected to enable at least a portion of the silicon nitride layer 212 to transform into silicon oxynitride.

The energy of the oxygen ions is selected to be low enough that the oxygen ions do not to penetrate into the bottom oxide layer 211. As a result, the oxygen ions do not stimulate damage to the bottom oxide layer 211. In accordance with one embodiment of the present invention, an oxygen plasma etcher, of the type usually employed for resist etching in semiconductor processing, can be used to create an oxygen plasma, which introduces the low-energy oxygen ions to region 212A of silicon nitride layer 212. The oxygen ions of the oxygen plasma can be derived from an oxygen-containing gas, such as nitrogen oxide (NO) or nitrous oxide (N₂O). In alternate embodiments, low-energy oxygen ions are implanted into the top interface of silicon nitride layer 212 from a source not in direct contact with plasma (i.e., a non-plasma source). For example, ultra-low energy vacuum implanters may be used so that the oxygen plasma is not directly in contact with the processed surface of silicon nitride layer 212. A separate source (which can be a plasma) produces oxygen ions, which are transported to the processed surface by being accelerated or decelerated. The thermal budget associated with implanting the oxygen ions in the silicon nitride layer 212 is relatively small, as the temperature of the oxygen plasma is relatively low (e.g., in the range of about 100 to 300° C.).

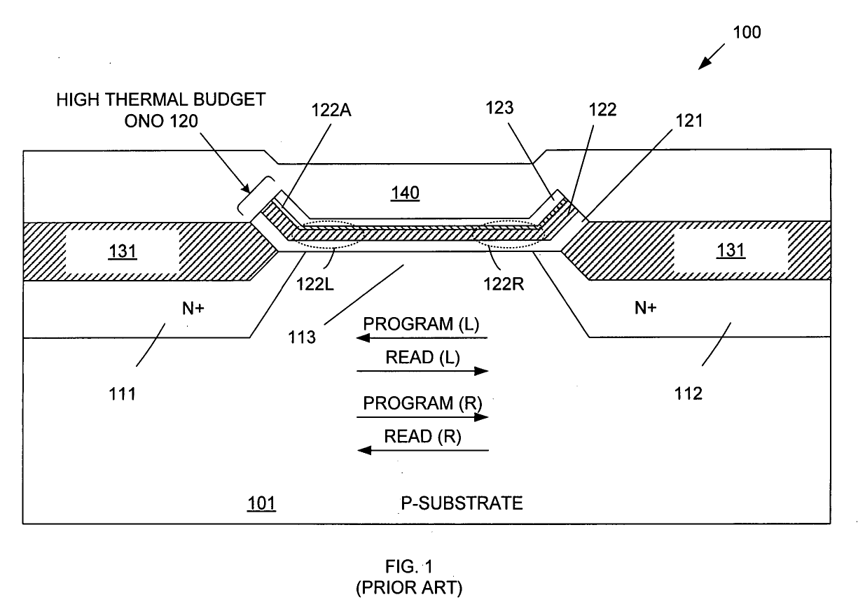

As shown in FIG. 2D, the oxygen-processed silicon nitride layer 212 is covered with an upper oxide layer 213. The upper oxide layer 213 can be, for example, a high-temperature silicon oxide (HTO), which is deposited at a temperature of about 800° C. Because oxygen ions were previously implanted into silicon nitride layer 212, it is not necessary to oxidize a portion of the silicon nitride layer 212 during the formation of upper oxide layer 213. Consequently, the thermal budget required to form upper oxide layer 213 is significantly less than the thermal budget required to form the conventional upper oxide layer 123 of the standard process flow (FIG. 1).

In an alternate embodiment, the upper oxide layer 213 is formed by chemical vapor deposition, which requires a relatively low thermal budget. Again, this is possible because oxygen ions were previously introduced into silicon nitride layer, thereby enabling the formation of silicon oxynitride within a portion of silicon nitride layer 212, without requiring the high thermal budget associated with a conventional ONO structure.

In yet another embodiment, upper oxide layer 213 is formed by depositing a high-dielectric oxide, such as aluminum oxide (Al₂O₃), hafnium dioxide (HfO₂), or zirconium oxide (ZrO₂).

An anneal of the entire resulting ONO structure 210 can be performed in an oxygen-containing environment at temperatures in the range of about 650 to 1150° C. Note that if higher temperatures within this range are used, the duration of the anneal is reduced, thereby maintaining a low thermal budget.

When processing is complete, the oxygen ions in region 212A combine with the surrounding silicon nitride, thereby creating silicon oxynitride region 212B.

Specific samples, which were actually fabricated using the methods of the present invention, will now be described. The samples described below were created by exposing upper surfaces of silicon nitride layers to oxygen plasma, which was an RF plasma with a power of about 550 Watts. During this exposure, the oxygen pressure was less than about 50 torr, and the temperature was within the range of about 100 to 300° C. Various samples were prepared, wherein the duration of the exposure to the oxygen plasma was 30, 60 and 120 seconds. No special cleans were performed before the oxygen plasma processing step.

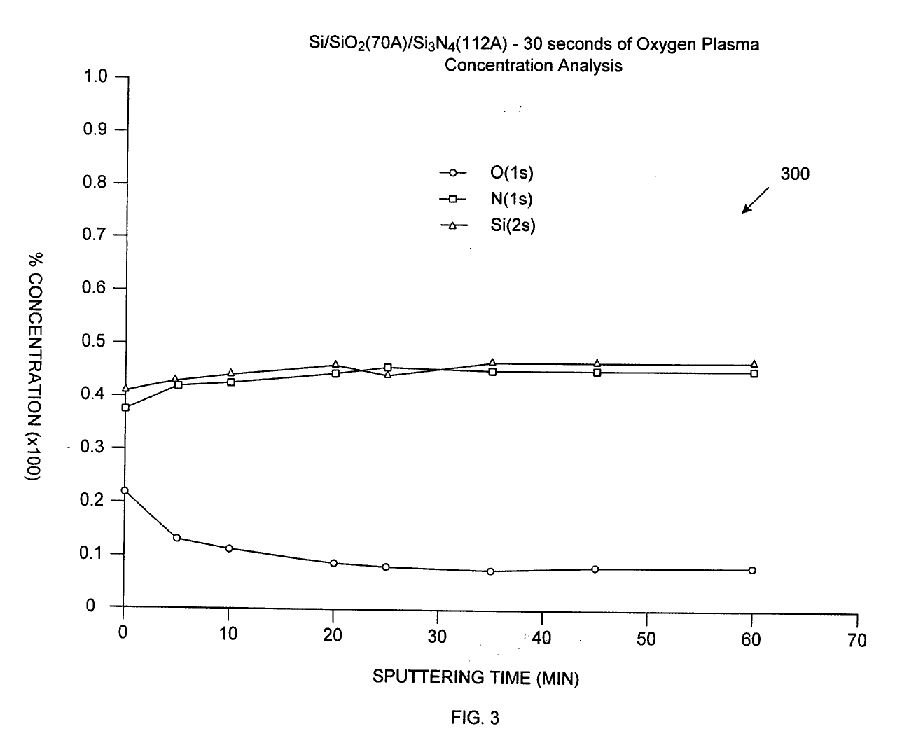

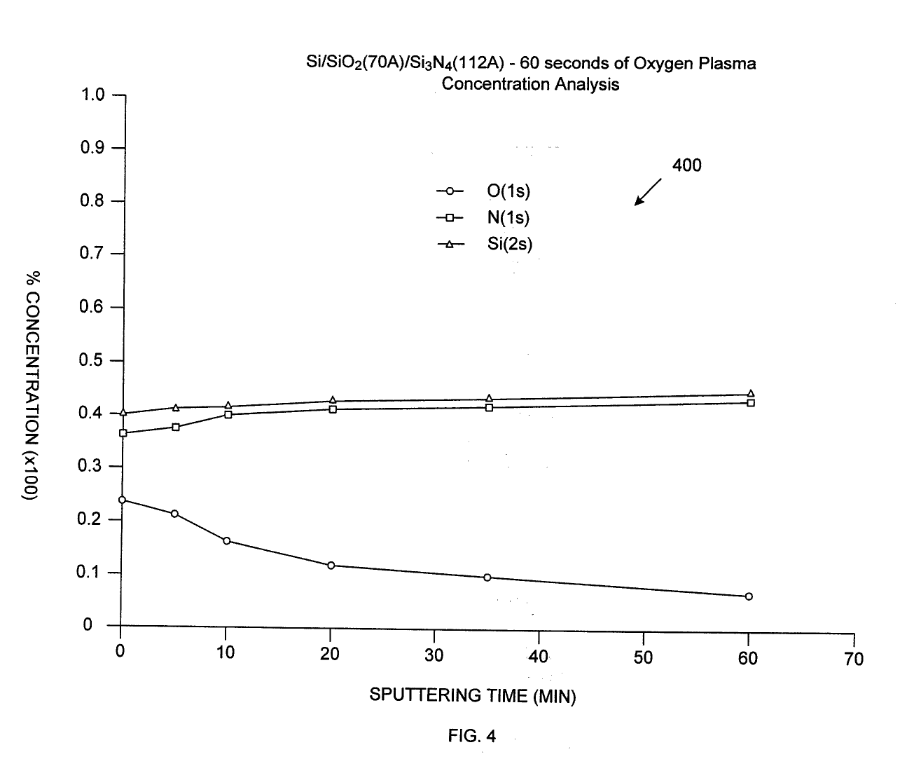

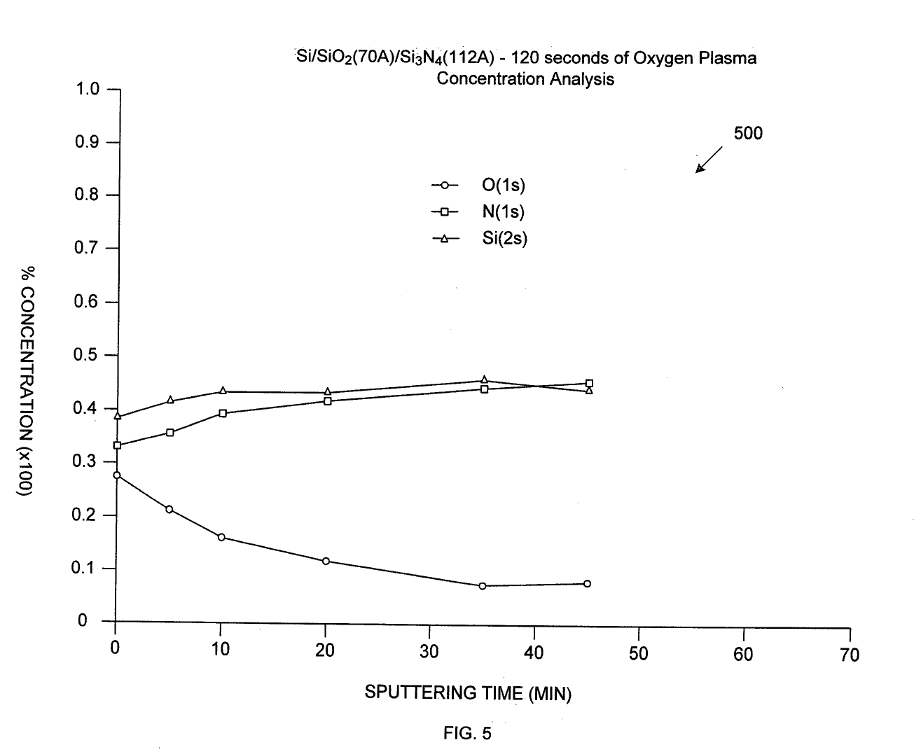

After plasma processing, the element content of the dielectric stack was analyzed. FIGS. 3, 4 and 5 illustrate graphs 300, 400 and 500, respectively, which illustrate various concentration percentages in the samples exposed to the oxygen plasma for 30, 60 and 120 seconds, respectively. As illustrated in FIGS. 3, 4 and 5, the oxygen concentration percentage at the upper surfaces of silicon nitride layers that were exposed for 30, 60 and 120 seconds, respectively, were 22%, 24% and 27%, respectively.

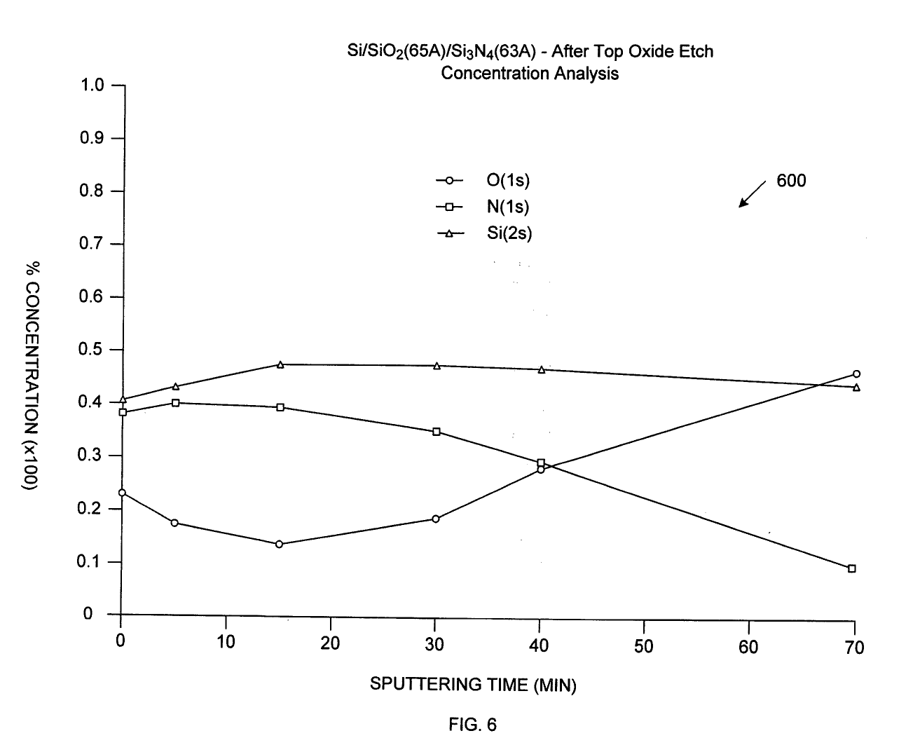

In order to compare the concentrations illustrated in FIGS. 3, 4 and 5 with the chemical composition of a conventional high thermal budget ONO structure, the top oxide layers of high thermal budget ONO structures (e.g., ONO structure 120; FIG. 1) were chemically etched using a HF solution diluted with a buffer agent (NH₄F). FIG. 6 is a graph 600 illustrating the concentration percentages of oxygen, nitrogen and silicon measured in the silicon nitride layers of the high thermal budget ONO structures that had the associated top oxide layers removed. The etched samples included a bottom oxide layer of silicon oxide with a thickness of about 65 Angstroms. The silicon nitride layer had a thickness of about 63 Angstroms after the top oxide layer was etched. As illustrated in FIG. 6, the measured oxygen concentration in the silicon nitride layers of the etched samples was about 23%.

As described above, the low thermal budget ONO structure 210 of the present invention advantageously exhibits a chemical composition similar to a conventional high thermal budget ONO structure 120 (FIG. 1). X-ray photoelectron Spectroscopy (XPS) was used to generate the graphs 300, 400, 500 and 600 of FIGS. 3, 4, 5 and 6.

Non-volatile memory cells fabricated in accordance with the parameters associated with FIGS. 3, 4, 5 and 6 all exhibited similar values of threshold voltage (Vt), drain current (Id), breakdown voltage between the drain and the source when the gate is shorted to the source (BVDss), and programming and erase times.

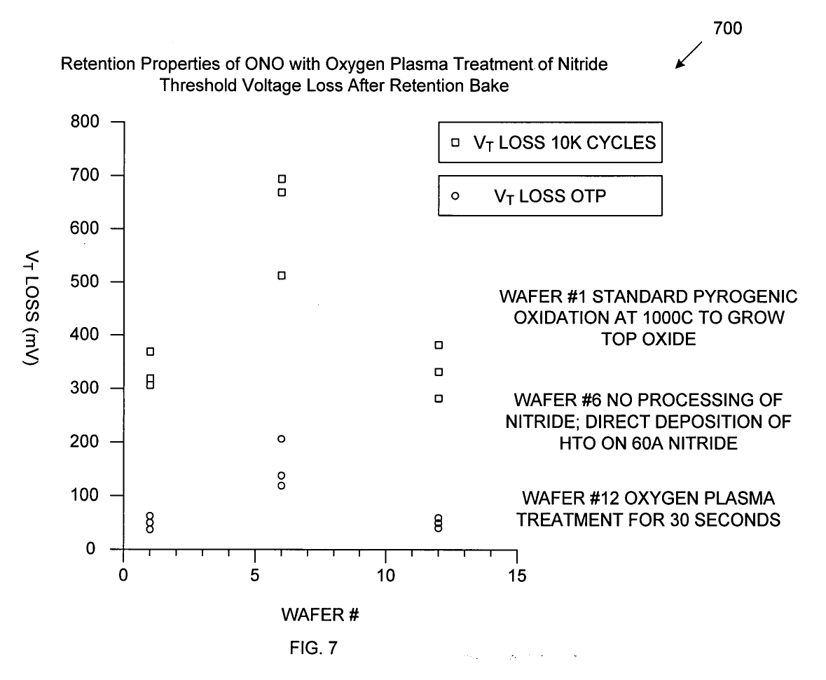

FIG. 7 is a graph 700 that compares the threshold voltage loss associated with three groups of NROM cells. On a first wafer (#1), NROM cells were fabricated with a conventional high thermal budget ONO structure. On a second wafer (#12), NROM cells were fabricated in accordance with the present invention. On a third wafer (#6), NROM cells were fabricated in accordance with the teachings of FIGS. 2A-2D above; however, the silicon nitride layer on the third wafer was not exposed to oxygen. The upper oxide layer of the third wafer was formed by the direct deposition of HTO.

As illustrated in FIG. 7, one-time programming (OTP) retention loss, which involves programming a fresh NROM cell to an initial threshold voltage of +1.8 Volts, and then performing a retention bake for 1 hour at 250° C., was substantially the same for NROM cells fabricated in accordance with the present invention (wafer #12) and NROM cells fabricated with a conventional high thermal budget ONO structure (wafer #1). In contrast, NROM cells fabricated without exposing the silicon nitride layer to oxygen (wafer #6) exhibited a much greater retention loss (i.e., higher threshold voltage decrease) after the retention bake.

Similarly, retention loss after performing cycling for 10,000 cycles and then performing a retention bake for 1 hour at 250° C., was substantially the same for NROM cells fabricated in accordance with the present invention (wafer #12) and NROM cells fabricated with a conventional high thermal budget ONO structure (wafer #1). Again, NROM cells fabricated without exposing the silicon nitride layer to oxygen (wafer #6) exhibited much greater retention loss.

Thus, the performed tests indicate that NROM cells fabricated with a conventional high thermal budget ONO structure 120 exhibit similar electrical performance as NROM cells fabricated with the ONO structure 210 of the present invention, even though the thermal budget associated with the ONO structure 210 of the present invention is much less.

The method of the present invention allows for much more flexibility in the design of embedded SONOS memories. For example, it is possible to fabricate the ONO structure of the present invention after diffusion and well regions have been formed. This advantageously allows the ONO structure of the present invention to be more easily integrated with a conventional CMOS process. When integrated with a conventional CMOS process, the ONO structure of the present invention advantageously eliminates reliability problems in the CMOS portion of the microcircuit that accompanies most flash memory integration schemes. The ONO structure of the present invention will therefore lower product price and increase product reliability.

Although the invention has been described in connection with several embodiments, it is understood that this invention is not limited to the embodiments disclosed, but is capable of various modifications, which would be apparent to a person skilled in the art. Thus, the invention is limited only by the following claims.

We claim:

1. A method of forming an oxide-nitride-oxide (ONO) structure, comprising:
forming a first oxide layer over a substrate;
forming a silicon nitride layer over the first oxide layer;
introducing oxygen into a top interface of the silicon nitride layer; and then forming a second oxide layer over the silicon nitride layer.

2. The method of claim 1, wherein the step of introducing oxygen comprises creating an oxygen plasma, wherein oxygen ions from the oxygen plasma bombard the top interface of the silicon nitride layer.

3. The method of claim 2, further comprising deriving the oxygen ions from an oxygen-containing gas.

4. The method of claim 3, wherein the oxygen-containing gas comprises nitrogen oxide (NO) or nitrous oxide (N₂O).

5. The method of claim 2, further comprising controlling an energy of the oxygen ions to be low enough that the oxygen ions do not penetrate into the first oxide layer.

6. The method of claim 2, wherein the second oxide layer comprises a high-temperature silicon oxide (HTO), which is deposited at a temperature of about 800° C.

7. The method of claim 2, wherein the second oxide layer is silicon oxide formed by chemical vapor deposition.

8. The method of claim 7, further comprising annealing the first oxide layer, the silicon nitride layer and the second oxide layer at temperatures in the range of about 650 to 1150° C. in an oxygen-containing ambient environment.

9. The method of claim 2, wherein the step of forming the second oxide layer comprises forming a high-dielectric oxide, such as aluminum oxide (Al₂O₃), hafnium dioxide (HfO₂), or zirconium oxide (ZrO₂).

10. The method of claim 1, further comprising forming the first oxide layer by thermally oxidizing a portion of the substrate.

11. The method of claim 10, wherein the substrate comprises silicon and the first oxide layer comprises silicon oxide.

12. The method of claim 1, wherein the step of introducing oxygen comprises implanting low-energy oxygen ions into the top interface of the silicon nitride layer from a non-plasma source.
